(19) United States
(12) Patent Application Publication
(10) Pub. No.: US 2013/0154457 A1
(43) Pub. Date: Jun. 20, 2013

(54) HARD DISK DRIVE FILLER

(71) Applicants: WEI-CHIH KUO, New Taipei City (TW); BO-CHUN LIN, New Taipei City (TW)

(72) Inventors: WEI-CHIH KUO, New Taipei City (TW); BO-CHUN LIN, New Taipei City (TW)

(21) Appl. No.: 13/604,522

(22) Filed: Sep. 5, 2012

(30) Foreign Application Priority Data
Dec. 16, 2011 (TW) 100146866

(51) Int. Cl. H05K 7/00; H05K 5/00

(52) U.S. Cl. 312/223.2

(57) ABSTRACT

A hard disk drive filler (HDD filler) detachably installed in a case is disclosed. The HDD filler has a frame body, a guiding device, and a gravitational sliding device, wherein the frame body defines a bottom surface and a top surface corresponding to the bottom surface. The guiding device is situated on the frame body and combines with the gravitational sliding device. The gravitational sliding device is confined and guided by the guiding device, such that the gravitational sliding device can slide along a certain direction for staying within or exposing at least a part of the gravitational sliding device to the frame body due to gravity. If the frame body is installed in the case while the bottom surface is upward, the gravitational sliding device slides and is guided by the guiding device to be partly exposed to the frame body to stop the installation.

### BACKGROUND OF THE INVENTION

1. Field of the Invention

The present invention relates to a hard disk drive filler; more particularly, the present invention relates to a hard disk drive filler with a foolproof device.

2. Description of the Related Art

The two most common kinds of hard disk drive fillers (HDD Filler) are shown in FIG. 1 and FIG. 1a. In the prior art, the top surface 120 of the hard disk drive filler of the prior art 100 illustrated in FIG. 1 is the only correct method to install the hard disk drive filler of the prior art 100 in a server or a storage case because devices for removing electromagnetic interference are mounted on the bottom surface 130 of the hard disk drive filler of the prior art 100. However, there is no foolproof device installed in the hard disk drive filler of the prior art 100. Therefore, the technical staff cannot immediately know whether or not the hard disk drive filler of the prior art 100 is installed in the server or storage case correctly. The installation error can be identified only when the hard disk drive filler of the prior art 100 does not work, which is not convenient for the technical personnel or user.

In FIG. 1a, there is a foolproof device 110a in the hard disk drive filler of the prior art 100a, but this kind of foolproof device 110a does not work effectively. If the direction of installation is wrong, the hard disk drive filler of the prior art 100a can still be installed in the server or storage case if technical personnel apply more force. A hard disk drive filler of the prior art 100a that is not installed correctly can still work properly, but it cannot match with the server or the storage case smoothly. In addition, the appearance is not as good as the appearance of correct installation.

Therefore, there is a need to provide a new hard disk drive filler to solve the problem of the prior art.

### SUMMARY OF THE INVENTION

It is an object of the present invention to provide a hard disk drive filler with a foolproof device.

To achieve the abovementioned object, the hard disk drive filler of the present invention is detachably installed in a case. The hard disk drive filler comprises a frame body, a guiding device, and a gravitational sliding device, wherein the frame body defines a bottom surface and a top surface corresponding to the bottom surface. The guiding device is situated in the frame body. The gravitational sliding device is combined with the guiding device. The gravitational sliding device is confined and guided by the guiding device, such that the gravitational sliding device can slide along a direction to stay within the frame body or at least a part of the gravitational sliding device is exposed to the frame body due to gravity. Applying the abovementioned structure, if the hard disk drive filler is installed in the case while the bottom surface is upward, the gravitational sliding device slides due to gravity and is guided by the guiding device to be partly exposed to the frame body, and the case blocks the frame body from entering the case.

According to one embodiment of the present invention, the guiding device is a dowel pin.

According to another embodiment of the present invention, the guiding device is an L-shaped stop.

The hard disk drive filler of the present invention prevents installation of the hard disk drive filler in the case in a wrong direction.

### BRIEF DESCRIPTION OF THE DRAWINGS

FIG. 1 illustrates a schematic drawing of the hard disk drive filler of the prior art according to one embodiment.

FIG. 1a illustrates a schematic drawing of the hard disk drive filler of the prior art according to another embodiment.

FIG. 2 illustrates a schematic drawing of the hard disk drive filler of the present invention according to one embodiment when the bottom surface is upward.

FIG. 2a illustrates a schematic drawing of the installation of the hard disk drive filler of the present invention according to one embodiment when the bottom surface is upward.

FIG. 3 illustrates a schematic drawing of the hard disk drive filler of the present invention according to one embodiment when the top surface is upward.

FIG. 3a illustrates a schematic drawing of the installation of the hard disk drive filler of the present invention according to one embodiment when the top surface is upward.

FIG. 4 illustrates a schematic drawing of the hard disk drive filler of the present invention according to another embodiment when the top surface is upward.

FIG. 4a illustrates a schematic drawing of the hard disk drive filler of the present invention according to another embodiment when the bottom surface is upward.

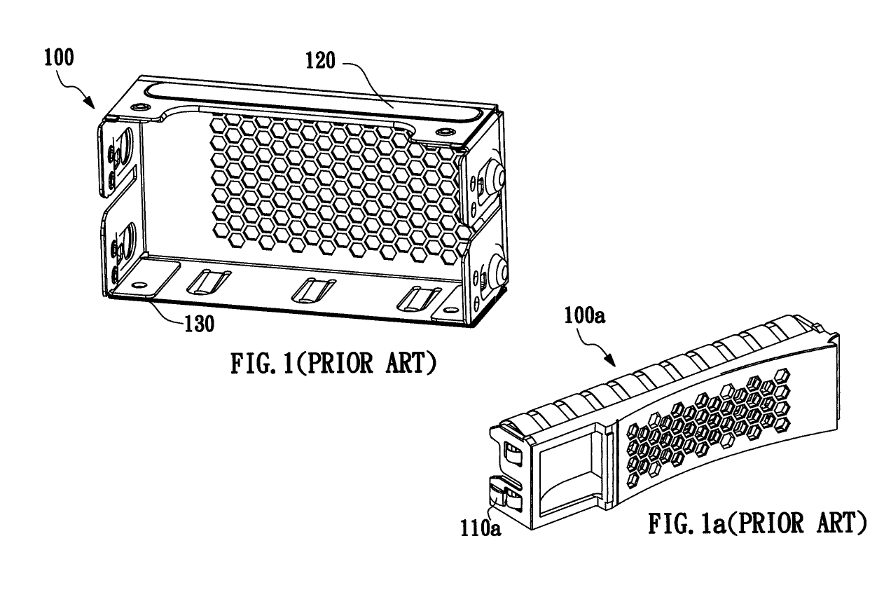

### DETAILED DESCRIPTION OF THE PREFERRED EMBODIMENT

These and other objects and advantages of the present invention will become apparent from the following description of the accompanying drawings, which disclose several embodiments of the present invention. It is to be understood that the drawings are to be used for purposes of illustration only, and not as a definition of the invention.

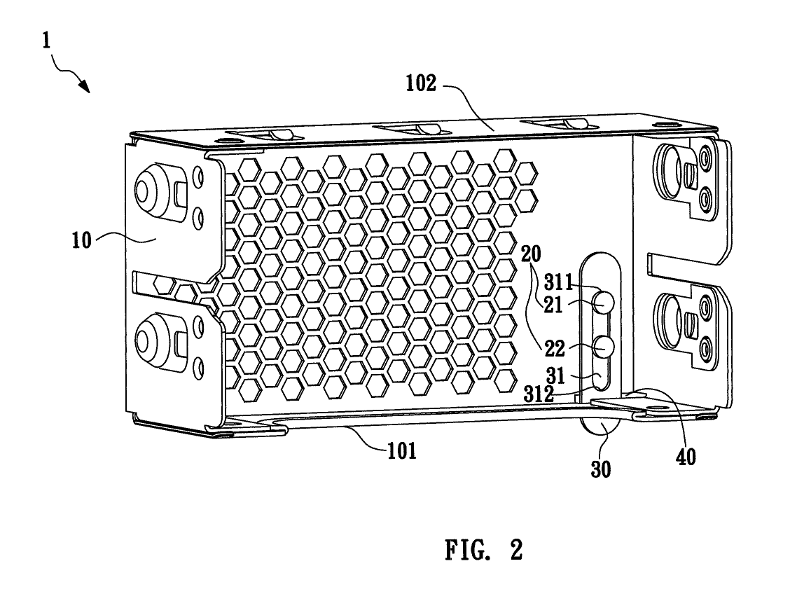

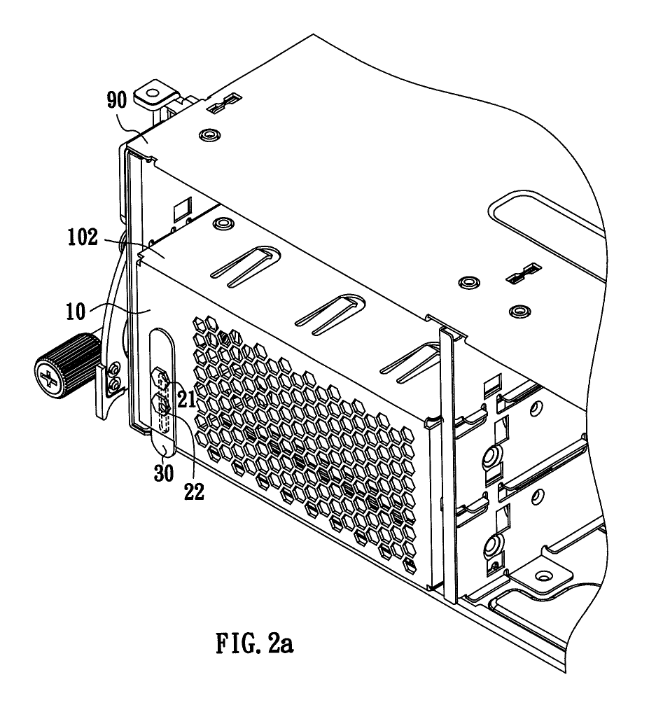

Please refer to FIG. 2 and FIG. 2a for the hard disk drive filler according to one embodiment of the present invention. FIG. 2 illustrates a schematic drawing of the hard disk drive filler of the present invention according to one embodiment when the bottom surface is upward. FIG. 2a illustrates a schematic drawing of an installed hard disk drive filler of the present invention according to one embodiment when the bottom surface is upward.

As shown in FIG. 2, the hard disk drive filler 1 of the present invention comprises a frame body 10, a guiding device 20, a gravitational sliding device 30, and a hole 40, wherein the guiding device 20 of the present embodiment is a dowel pin. The guiding device 20 of the present embodiment further comprises a first guiding device 21 and a second guiding device 22. The first guiding device 21, the second guiding device 22, and the gravitational sliding device 30 are situated in the frame body 10 or other suitable places. The frame body 10 defines a top surface 101 and a bottom surface 102 corresponding to the top surface 101; the gravitational sliding device 30 can be movably combined with the first guiding device 21 and the second guiding device 22, both of which are used for confining and guiding the gravitational sliding device 30 to execute a linear sliding displacement along a direction due to gravity in the frame body 10. The hole 40 is on the top surface 101, which is the same side as the first guiding device 21 and is located on the moving path of the gravitational sliding device 30 for allowing the gravitational sliding device 30 to be partly exposed to the frame body 10 via the hole 40. As shown in FIG. 2, the second guiding device 22 is situated between the first guiding device 21 and the bottom surface 102 such that the first guiding device 21, the second guiding device 22, and the hole 40 are all located on the same axis of the moving path of the gravitational sliding device 30. Therefore, when the bottom surface 102 of the hard disk drive filler 1 is upward, the gravitational sliding device 30 slides linearly along the direction of gravity, guided by the first guiding device 21 and the second guiding device 22, passes through the hole 40, and slides out of the frame body 10 to form the status shown in FIG. 2a. It is to be understood that the top surface 101 and the bottom surface 102 of the frame body 10 of the present invention can also be a top surface and a bottom surface of a non-entity object; for example, the top surface 101 can be an open space; i.e., the top surface 101 and the bottom surface 102 are two opposite sides of a space, and the open space of the top surface 101 can also be seen as a large hole 40.

In the embodiment of the present invention, the guiding device 20 comprises the first guiding device 21 and the second guiding device 22 with a round shape; however, the guiding device 20 can comprise only one guiding device, such as an oblong or a rectangular guiding device.

According to one embodiment of the present invention, as shown in FIG. 2, the gravitational sliding device 30 further comprises a hollow area 31; the hollow area 31 is used for combining with the first guiding device 21 and the second guiding device 22. When the bottom surface 102 of the hard disk drive filler 1 is upward, the gravitational sliding device 30 slides linearly along the direction of gravity, guided by the first guiding device 21 and the second guiding device 22, and stops sliding when the first end 311 of the hollow area 31 interferes with the first guiding device 21. According to one embodiment of the present invention, the first guiding device 21 and the second guiding device 22 for guiding the gravitational sliding device 30 to slide linearly are dowel pins; if the hollow area 31 touches any dowel pin, the gravitational sliding device 30 stops sliding. However, the present invention is not limited to the present embodiment; any element that can guide the gravitational sliding device 30 to slide linearly along the direction of gravity is suitable for the present invention.

As shown in FIG. 2a, the hard disk drive filler 1 of the present invention is located detachably in the case 90. In the present embodiment, it is incorrect to install the hard disk drive filler 1 when the bottom surface 102 is upward. If the hard disk drive filler 1 is installed in the case 90 when the bottom surface 102 is upward, the gravitational sliding device 30 slides along the direction of gravity and is exposed to the frame body 10, guided by the first guiding device 21 and the second guiding device 22. As a result, the frame body 10 is blocked by the case 90 because the bottom of the case 90 interferes with the gravitational sliding device 30 to prevent the hard disk drive filler 1 from being installed in an incorrect direction. It is to be understood that, to achieve a better sliding effect, the gravitational sliding device 30 must have a certain weight. The gravitational sliding device 30 of the present embodiment is made of a zinc coating on hot-dipped steel (SGCC), but the present invention is not limited to that design; any material with sufficient weight can be applied to the present invention, and the case 90 can be the case of a server or a storage case.

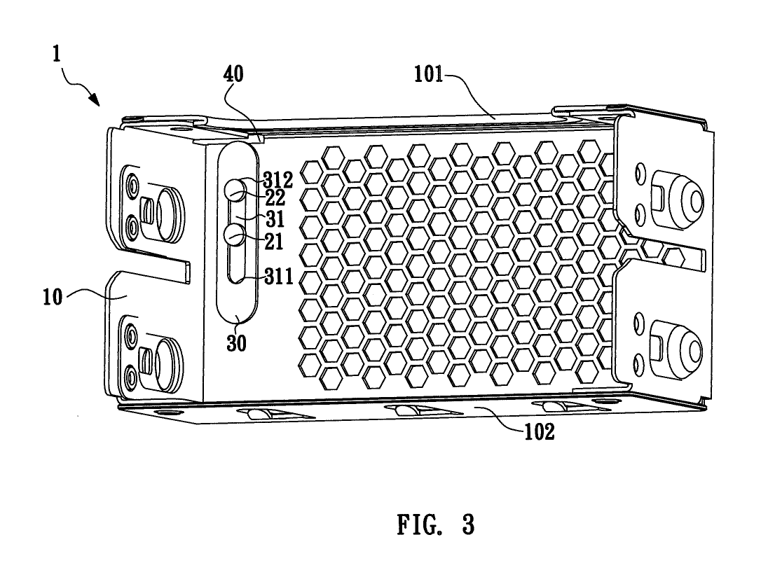

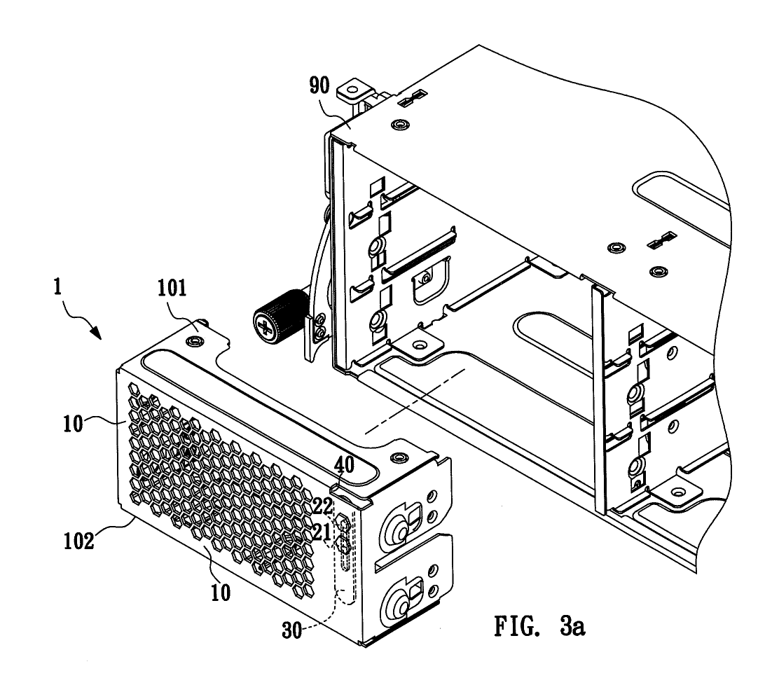

Please refer to FIG. 3 and FIG. 3a. FIG. 3 illustrates a schematic drawing of the hard disk drive filler of the present invention according to one embodiment when the top surface is upward. FIG. 3a illustrates a schematic drawing of the installation of the hard disk drive filler of the present invention according to one embodiment when the top surface is upward.

As shown in FIG. 3 and FIG. 3a, in the present embodiment, it is correct to install the hard disk drive filler 1 when the top surface 101 is upward. Therefore, when the top surface 101 of the hard disk drive filler 1 is upward, the gravitational sliding device 30 slides linearly along the direction of gravity, guided by the first guiding device 21 and the second guiding device 22, to stay within the frame body 10, such that the hard disk drive filler 1 can be installed in the case 90. As shown in FIG. 3, at this moment, the second end 312 of the hollow area 31 interferes with the second guiding device 22.

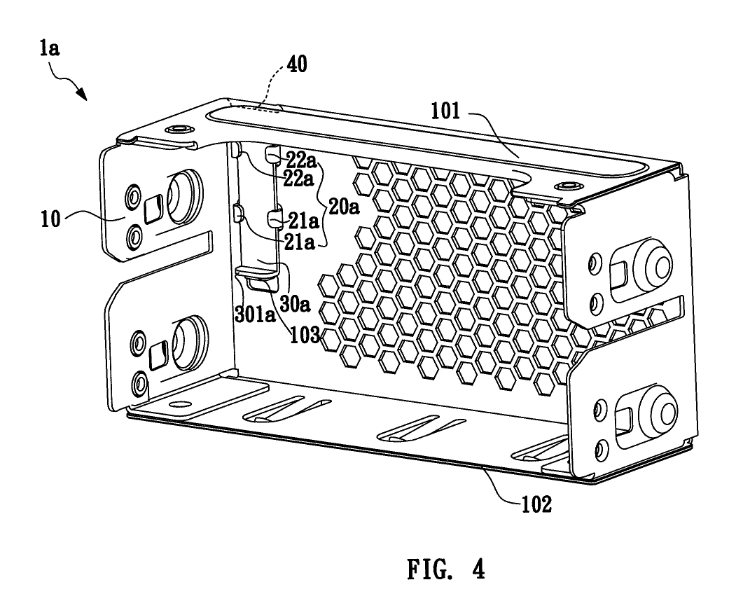

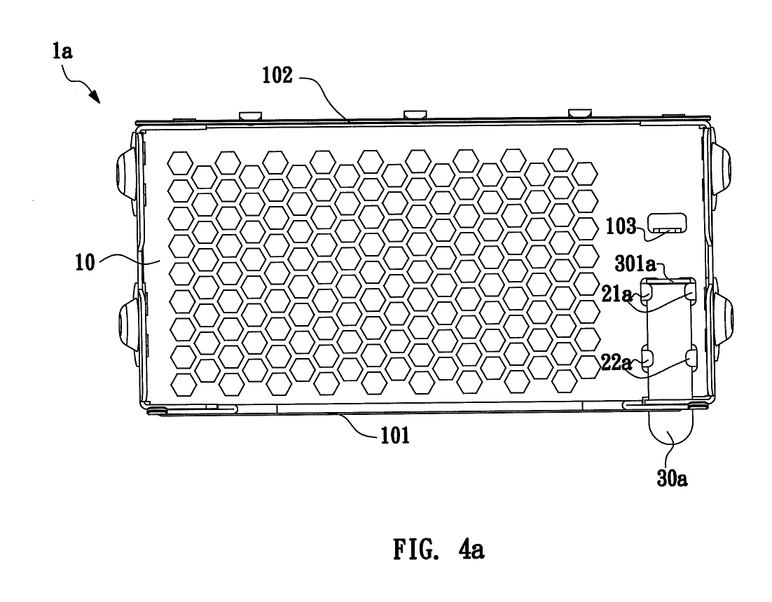

Please refer to FIG. 4 and FIG. 4a. FIG. 4 illustrates a schematic drawing of the hard disk drive filler of the present invention according to another embodiment when the top surface is upward. FIG. 4a illustrates a schematic drawing of the hard disk drive filler of the present invention according to another embodiment when the bottom surface is upward.

As shown in FIG. 4, the gravitational sliding device 30a of the hard disk drive filler 1a of the present invention is a slice body 30a. The slice body 30a comprises a blocking wall 301a. In the present embodiment, the guiding device 20a of the hard disk drive filler la of the present invention is an L-shaped stop. The first guiding device 21a and the second guiding device 22a of the guiding device 20a of the present embodiment are two individual L-shaped stops 21a, 22a, and the gravitational sliding device 30a is located in the space formed by the two L-shaped stops 21a, 22a. It is to be understood that, according to one embodiment of the present invention, the two L-shaped stops 21a, 22a are formed integrally from the frame body 10. As shown in FIG. 4, when the top surface 101 of the hard disk drive filler 1 is upward, the blocking wall 301a touches the supporting board 103 of the frame body 10; i.e., the gravitational sliding device 30a is motionless, and the gravitational sliding device 30a stays within the frame body 10 for facilitating installation.

As shown in FIG. 4a, when the bottom surface 102 of the hard disk drive filler is upward, the slice body 32 slides linearly along the direction of gravity, guided by the first guiding device 21 a and the second guiding device 22a, until the blocking wall 301a touches the two first guiding devices 21a, and a part of the gravitational sliding device 30a is exposed to the frame body 10 to block the frame body 10 from entering the case 90 for preventing incorrect installation.

Applying the abovementioned structure, when the hard disk drive filler 1 of the present invention is installed in the case 90 in the wrong way, the gravitational sliding device 30 will slide out of the frame body 10 and be exposed to the frame body 10 for blocking the frame body 10 from entering the case 90. Consequently, the technical personnel will immediately know that the orientation of the frame body 10 is incorrect and a correction can be made.

It is noted that the above-mentioned embodiments are only for illustration. It is intended that the present invention cover modifications and variations of this invention provided they fall within the scope of the following claims and their equivalents. Therefore, it will be apparent to those skilled in the art that various modifications and variations can be made to the structure of the present invention without departing from the scope or spirit of the invention.

What is claimed is:

1. A hard disk drive filler detachably installed in a case, the hard disk drive filler comprising:
a frame body defining a bottom surface and a top surface corresponding to the bottom surface;
a guiding device situated on the frame body; and
a gravitational sliding device combined with the guiding device and confined and guided by the guiding device such that the gravitational sliding device can slide along a direction to stay within the frame body or expose at least a part of it to the frame body due to gravity;
whereby, if the hard disk drive filler is installed in the case while the bottom surface is upward, the gravitational sliding device slides due to gravity and is guided by the guiding device to be partly exposed to the frame body and interferes with the case to block the frame body from entering the case.

2. The hard disk drive filler as claimed in claim 1, wherein the hard disk drive filler further comprises a hole, wherein the hole is situated on the top surface, and the hole is situated on a moving path of the gravitational sliding device for allowing a part of the gravitational sliding device to slide out of the frame body via the hole.

3. The hard disk drive filler as claimed in claim 1, wherein if the top surface of the hard disk drive filler is upward, the gravitational sliding device slides reversely into the frame body, guided by the guiding device, such that the gravitational sliding device stays completely within the frame body.

4. The hard disk drive filler as claimed in claim 2, wherein the guiding device of the hard disk drive filler comprises a first guiding device and a second guiding device; the first guiding device, the second guiding device, and the hole are situated on a same axis of the moving path of the gravitational sliding device.

5. The hard disk drive filler as claimed in claim 1, wherein the gravitational sliding device further comprises a hollow area for being movably connected to the guiding device.

6. The hard disk drive filler as claimed in claim 1, wherein if the bottom surface of the hard disk drive filler is upward, the gravitational sliding device slides out of the frame body due to gravity and the guiding of the guiding device and stops sliding when a first end of the hollow area interferes with the guiding device and the gravitational sliding device is partly exposed to the frame body.

7. The hard disk drive filler as claimed in claim 6, wherein if the top surface of the hard disk drive filler is upward, the gravitational sliding device slides due to gravity and the guiding of the guiding device and stops sliding when a second end of the hollow area interferes with the guiding device.

8. The hard disk drive filler as claimed in claim 1, wherein the guiding device is a dowel pin.

9. The hard disk drive filler as claimed in claim 1, wherein the guiding device is an L-shaped stop.

10. The hard disk drive filler as claimed in claim 9, wherein the guiding device comprises two L-shaped stops.

11. The hard disk drive filler as claimed in claim 9, wherein the gravitational sliding device is a slice body which comprises a blocking wall; if the bottom surface of the hard disk drive filler is upward, the slice body is guided by the L-shaped stop and slides due to gravity until the blocking wall interferes with the L-shaped stop to stop the installation.

12. The hard disk drive filler as claimed in claim 9, wherein the L-shaped stop is formed integrally from the frame body.

13. The hard disk drive filler as claimed in claim 2, wherein the top surface can be an open space, and the hole is the open space.
